(19) United States
(12) Patent Application Publication
(10) Pub. No.: US 2026/0287654 A1
(43) Pub. Date: Sep. 24, 2026

(54) MEMORY DEVICES AND MEMORY SYSTEMS OUTPUTTING CODES

(71) Applicant: SK hynix Inc., Icheon-si Gyeonggi-do (KR)

(72) Inventors: Min Kyu MOON, Icheon-si Gyeonggi-do (KR); Kyung Jun CHO, Icheon-si Gyeonggi-do (KR)

(73) Assignee: SK hynix Inc., Icheon-si Gyeonggi-do (KR)

(21) Appl. No.: 19/299,970

(22) Filed: Aug. 14, 2025

(30) Foreign Application Priority Data
Mar. 24, 2025 (KR) 10-2025-0037441

(51) Int. Cl. G01R 31/317; G01R 31/28

(52) U.S. Cl. CPC G01R 31/31726; G01R 31/2812; G01R 31/31727

(57) ABSTRACT

The present disclosure provides a memory device including a base die, and a plurality of core dies stacked over the base die and connected to the base die using a plurality of through vias and a plurality of bump pads. The base die outputs a test code as a read code through an output pad in synchronization with a first edge of a test clock signal in a normal mode and outputs the test code as the read code through the output pad in synchronization with the first edge and a second edge of the test clock signal in an acceleration mode.

### CROSS-REFERENCE TO RELATED APPLICATIONS

The present application claims priority under 35 U.S.C §119(a) to Korean Application No. 10-2025-0037441, filed in the Korean Intellectual Property Office on March 24, 2025, the entire contents of which application is incorporated herein by reference.

### BACKGROUND

### 1. Technical Field

The present disclosure relates to memory devices and memory systems outputting codes.

### 2. Related Art

Stacked memory systems, such as high bandwidth memory (HBM) devices, are used in a wide range of applications due to their high bandwidth and energy efficiency. Unlike conventional memory systems that use parallel data buses, the stacked memory system includes a stacked memory device including a base chip and a plurality of memory chips interconnected by through silicon vias (TSVs). The stacked memory device includes a physical interface, such as a physical layer for communicating with a processor. The physical layer is designed for high-speed data transmission and efficient communication.

### SUMMARY

The present disclosure describes a memory device that may include a base die, and a plurality of core dies stacked over the base die and connected to the base die using a plurality of through vias and a plurality of bump pads. The base die may output a test code as a read code through an output pad in synchronization with a first edge of a test clock signal in a normal mode and may output the test code as the read code through the output pad in synchronization with the first edge and a second edge of the test clock signal in an acceleration mode.

The present disclosure describes a memory system that may include an interposer stacked over a substrate, and a memory device and a processor stacked over the interposer and connected to each other through wires formed in the interposer. The memory device may include a base die and a plurality of core dies stacked over the interposer, and the base die and the plurality of core dies may be connected to each other using a plurality of through vias and a plurality of bump pads. The base die may output a test code as a read code through an output pad in synchronization with a first edge of a test clock signal in a normal mode and may output the test code as the read code through the output pad in synchronization with the first edge and a second edge of the test clock signal in an acceleration mode.

The present disclosure describes a memory device that may a base die; and a plurality of core dies stacked over the base die and connected to the base die using a plurality of through vias and a plurality of bump pads. The base die is configured to: output a first selection clock signal through an output pad, a first edge of the first selection clock signal being in synchronization with only first edges of a test clock signal in a normal mode; and output a second selection clock signal through the output pad, a first edge of the second selection clock signal being in synchronization with both first and second edges of the test clock signal in an acceleration mode.

### BRIEF DESCRIPTION OF THE DRAWINGS

FIG. 1 illustrates a base die according to an embodiment of the present disclosure.

FIG. 2 illustrates a selection clock generation circuit according to an embodiment of the present disclosure.

FIG. 3 and FIG. 4 are timing diagrams during an operation of a selection clock generation circuit according to an embodiment of the present disclosure.

FIG. 5 is a block diagram illustrating a memory system according to an embodiment of the present disclosure.

### DETAILED DESCRIPTION

In the following description of embodiments, when a parameter is referred to as being “predetermined,” it may be intended to mean that a value of the parameter is determined in advance when the parameter is used in a process or an algorithm. The value of the parameter may be set when the process or the algorithm starts or may be set during a period in which the process or the algorithm is executed.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

The term “binary bit set” may mean a combination of logic levels of bits included in a signal. When the logic level of each of the bits included in the signal is changed, the logic bit set of the signal may be set differently. For example, when the signal includes two bits, when the logic level of each of the two bits included in the signal is "logic low level, logic low level", the logic bit set of the signal may be set as the first logic bit set, and when the logic level of each of the two bits included in the signal is “a logic low level and a logic high level”, the logic bit set of the signal may be set as the second logic bit set.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

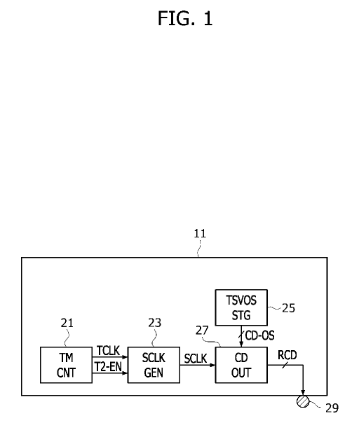

FIG. 1 illustrates a base die 11 according to an embodiment of the present disclosure.

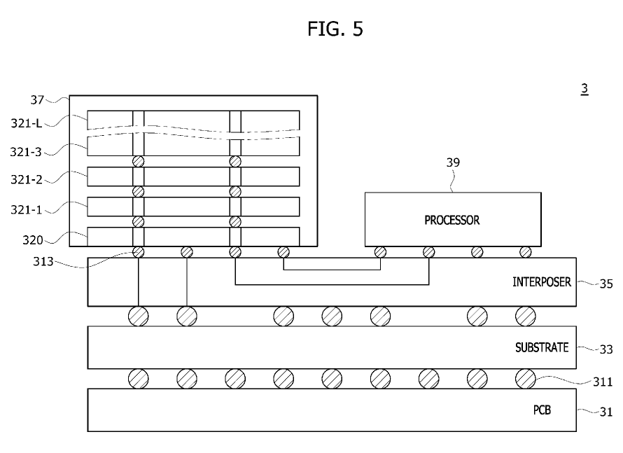

As shown in FIG. 1, the base die 11 includes a test mode control circuit (TM CNT) 21, a selection clock generation circuit (SCLK GEN) 23, a test code storage circuit (TSVOS STG) 25, a code output circuit (CD OUT) 27, and an output pad 29. A plurality of core dies, for example, core dies 321-1~321-L in FIG. 5 may be disposed over the base die 11. The base die 11 and the plurality of core dies are vertically connected to each other using micro-bump pads and through vias to form a memory device, for example, a memory device 37 in FIG. 5.

The test mode control circuit 21 generates a test clock signal TCLK and an acceleration mode signal T2-EN. The test clock signal TCLK and the acceleration mode signal T2-EN affect the output of a test code CD-OS in a test read mode, the test read mode including a normal mode and an acceleration mode. The test mode control circuit 21 generates the test clock signal TCLK that toggles in the test read mode. The test mode control circuit 21 generates a deactivated acceleration mode signal T2-EN in the normal mode and generates an activated acceleration mode signal T2-EN in the acceleration mode. Whether the test read mode is the normal mode or the acceleration mode can be determined by a signal stored in a mode register included in the test mode control circuit 21 or by an external signal applied from outside the test mode control circuit 21.

The selection clock generation circuit 23 is electrically connected to the test mode control circuit 21 and receives the test clock signal TCLK and the acceleration mode signal T2-EN from the test mode control circuit 21. The selection clock generation circuit 23 generates a selection clock signal SCLK for a test mode based on the test clock signal TCLK and the acceleration mode signal T2-EN. The selection clock generation circuit 23 outputs the test clock signal TCLK as the selection clock signal SCLK for the normal mode when the acceleration mode signal T2-EN is deactivated. The selection clock generation circuit 23 generates the selection clock signal SCLK including pulses generated at rising edges and falling edges of the test clock signal TCLK for the acceleration mode when the acceleration mode signal T2-EN is activated.

The test code storage circuit 25 stores the test code CD-OS. The test code CD-OS includes information on test results, such as an open circuit or a short circuit of the through vias, included in the base die 11 and each of the plurality of core dies. An open circuit of the through vias means that no current flows through the through vias, and a short circuit of the through vias means that excessive current flows through the through vias according to a connection between the through vias. The test code CD-OS includes a plurality of bits, and a binary bit set of the plurality of bits included in the test code CD-OS may correspond to at least one through via in which an open circuit or a short circuit is determined, among the through vias included in the base die 11 and each of the plurality of core dies. For example, when the through vias included in the base die 11 and each of the plurality of core dies include through vias of a first column and through vias of a second column, which are connected using micro-bump pads, the test code CD-OS including bits having a first binary bit set may correspond to the through vias of the first column, and the test code CD-OS including bits having a second binary bit set may correspond to the through vias of the second column.

The code output circuit 27 is electrically connected to the selection clock generation circuit 23 and the test code storage circuit 25, receiving the selection clock signal SCLK from the selection clock generation circuit 23 and receiving the test code CD-OS from the test code storage circuit 25. The code output circuit 27 outputs a read code RCD to the output pad 29 based on the selection clock signal SCLK and the test code CD-OS. The code output circuit 27 outputs the test code CD-OS as the read code RCD through the output pad 29 according to the selection clock signal SCLK generated from the test clock signal TCLK in the normal mode. The code output circuit 27 outputs the test code CD-OS as the read code RCD through the output pad 29 in synchronization with a rising edge of the test clock signal TCLK in the normal mode. The code output circuit 27 outputs the test code CD-OS as the read code RCD through the output pad 29 according to the selection clock signal SCLK including pulses generated at the rising edge and falling edge of the test clock signal TCLK in the acceleration mode. The code output circuit 27 outputs the test code CD-OS as the read code RCD through the output pad 29 in synchronization with the rising edge and falling edge of the test clock signal TCLK in the acceleration mode.

As described, in the test read mode in which the test code CD-OS including test results such as open circuit or short circuit included in the base die 11 and each of the plurality of core dies is output, test time can be reduced by providing an acceleration mode in which pulses are generated for each edge of the test clock signal TCLK to output the test code CD-OS.

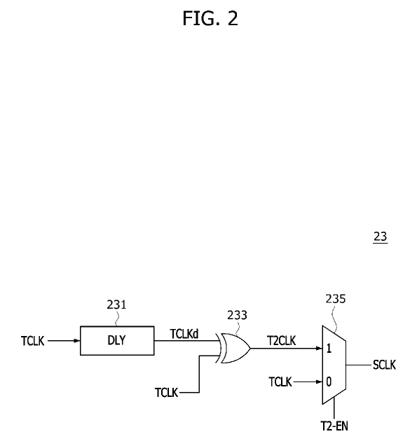

FIG. 2 illustrates a selection clock generation circuit 23 according to an embodiment of the present disclosure, for example, as shown in FIG. 1.

As shown in FIG. 2, the selection clock generation circuit 23 includes a delay unit (DLY) 231, an acceleration clock generator 233, and a selector 235.

The delay unit 231 delays a test clock signal TCLK by a preset delay period to generate a delayed test clock signal TCLKd. The delay period is a period for setting a pulse width of an acceleration clock signal T2CLK and may be implemented in various ways depending on the embodiment.

The acceleration clock generator 233 is electrically connected to the delay unit 231 and receives the delayed test clock signal TCLKd from the delay unit 231. The acceleration clock generator 233 performs an exclusive OR operation based on the test clock signal TCLK and the delayed test clock signal TCLKd to generate the acceleration clock signal T2CLK. The acceleration clock generator 233 generates the acceleration clock signal T2CLK that includes pulses generated during a period in which a phase of the test clock signal TCLK and a phase of the delayed test clock signal TCLKd are different. The acceleration clock generator 233 generates the acceleration clock signal T2CLK including pulses generated at the rising edges and falling edges of the test clock signal TCLK. A pulse width of the acceleration clock signal T2CLK is set to a preset delay period of the delay unit 231. The rising edge of the test clock signal TCLK means a point in time at which the test clock signal TCLK transitions from a logic low level to a logic high level, and the falling edge of the test clock signal TCLK means a point in time at which the test clock signal TCLK transitions from a logic high level to a logic low level.

The selector 235 is electrically connected to the acceleration clock generator 233 and receives the acceleration clock signal T2CLK from the acceleration clock generator 233. The selector 235 generates a selection clock signal SCLK based on an acceleration mode signal T2-EN, the test clock signal TCLK, and the acceleration clock signal T2CLK. When a deactivated acceleration mode signal T2-EN is received in a normal mode, the selector 235 outputs the test clock signal TCLK, received through a first terminal "0”, as the selection clock signal SCLK. When an activated acceleration mode signal T2-EN is received in an acceleration mode, the selector 235 outputs the acceleration clock signal T2CLK, received through a second terminal "1", as the selection clock signal SCLK.

When the acceleration mode signal T2-EN is deactivated, the selection clock generation circuit 23 outputs the test clock signal TCLK as the selection clock signal SCLK in the normal mode. When the acceleration mode signal T2-EN is activated, the selection clock generation circuit 23 generates the selection clock signal SCLK including pulses generated at rising edges and falling edges of the test clock signal TCLK in the acceleration mode.

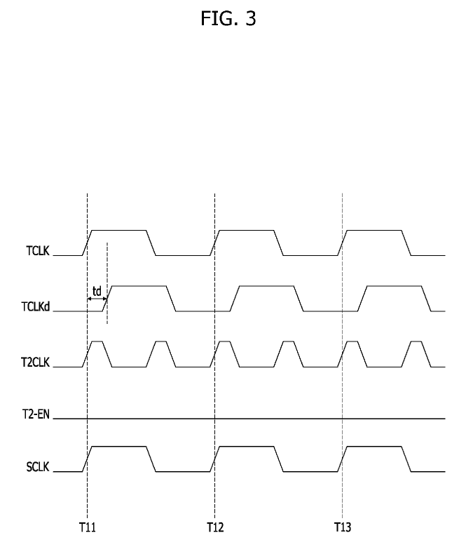

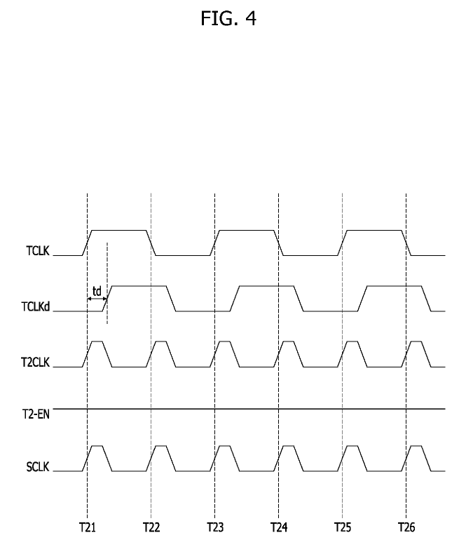

FIG. 3 and FIG. 4 are timing diagrams during an operation of a selection clock generation circuit 23 according to an embodiment of the present disclosure.

As shown in FIG. 3, the selection clock generation circuit 23 generates an acceleration clock signal T2CLK based on a delayed test clock signal TCLKd, which is obtained by delaying a test clock TCLK by a delay period td, and generates the test clock signal TCLK. The selection clock generation circuit 23 outputs the test clock signal TCLK as a selection clock signal SCLK when a deactivated acceleration mode signal T2-EN, deactivated at a logic low level, is received in a normal mode. Because the selection clock signal SCLK is generated from the test clock signal TCLK, the selection clock signal SCLK is generated at time points T11, T12, and T13 when the rising edges of the test clock signal TCLK occur.

As shown in FIG. 4, the selection clock generation circuit 23 generates the acceleration clock signal T2CLK based on the delayed test clock signal TCLKd, obtained by delaying the test clock TCLK by the delay period td, and generates the test clock signal TCLK. The selection clock generation circuit 23 outputs the acceleration clock signal T2CLK as the selection clock signal SCLK when an activated acceleration mode signal T2-EN, activated at a logic high level, is received in the acceleration mode. Because the selection clock signal SCLK is generated from the acceleration clock signal T2CLK, the selection clock signal SCLK is generated at time points T21, T23, and T25 when the rising edges of the test clock signal TCLK occurs and at time points T22, T24, and T26 when the falling edges of the test clock signal TCLK occur.

FIG. 5 is a block diagram illustrating a memory system 3 according to an embodiment of the present disclosure.

As shown in FIG. 5, the memory system 3 includes a printed circuit board (PCB) 31, a substrate 33, an interposer 35, a memory device 37, and a processor 39.

The printed circuit board 31 connects various electronic components to each other to form electronic circuits. The electronic circuits may include the memory system 3. A copper (Cu) layer, a solder mask, a silk screen, and so forth are formed on the printed circuit board 31. Circuit paths that transmit or transfer signals or power are formed in the copper (Cu) layer. The solder mask prevents damage to the circuits and protects a specific region where components are soldered. The silk screen indicates location or information for the electronic components as characters or symbols printed on a surface of the printed circuit board 31.

The substrate 33 is disposed over the printed circuit board 31 with bump pads in between, for example, bump pads 311 and mechanically supports the interposer 35, the memory device 37, and the processor 39. The substrate 33 functions as a physical base for the printed circuit board 31 and is an insulator. The substrate 33 may include materials, such as FR4 that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 35 is disposed over the substrate 33 with bump pads therebetween and includes wires that connect electronic components, for example, the memory device 47 and the processor 39, that have form factors or pin arrangements that do not match or have different spacing. The interposer 35 may convert signals to communicate on different interfaces, such as DDR, HBM, PCle.

The memory device 37 is disposed over the interposer 35 with pads therebetween, for example, micro-bump pads 313. The memory device 37 stores data received from the processor 39 or outputs the stored data to the processor 39 under the control of the processor 39. The memory device 37 includes a base die 320 and a plurality of core dies 321-1 to 321-L, where L is an integer greater than 1. The core dies 321-1 to 321-L are stacked over the base die 320 with micro-bump pads therebetween. The base die 320 and the core dies 321-1 to 321-L are vertically connected to each other using through vias and micro-bump pads. The base die 320 controls efficient data transmission between the processor 39 and the core dies 321-1 to 321-L. The base die 320 receives input/output power supply voltage (voltage drain for IO also referred to as output stage drain power voltage) VDDQ as an operating voltage utilized during operations of internal circuits included in the base die 320. The base die 320 receives the input/output power voltage VDDQ from the printed circuit board 31 through the substrate 33 and the interposer 35. The input/output power voltage VDDQ is a voltage supplied to buffers that transmit data and is distinguished or different from the power supply voltage VDD. The core dies 321-1 to 321-L use a peripheral voltage VPERI as an operating voltage during operations of the internal circuits included in the core dies 321-1 to 321-L. The core dies 321-1 to 321-L generate the peripheral voltage VPERI from the power supply voltage VDD received through the base die 320. The core dies 321-1 to 321-L generate the peripheral voltage VPERI at a lower voltage level than the input/output power voltage VDDQ and use the peripheral voltage VPERI as an operating voltage. Each of the core dies 321-1 to 321-L includes a plurality of channel regions, for example, eight channel regions or sixteen channel regions that operate independently. Each of the plurality of channel regions is allocated with a channel operating independently to receive or transmit data. The number L of core dies 321-1 to 321-L may be four, eight, twelve, sixteen, and so forth. For example, when each of the core dies 321-1 to 321-12 has eight channels, the core dies 321-1 to 321-4, the core dies 321-5 to 321-8, and the core dies 321-9 to 321-12 each include thirty-two channel regions, and each transmit and receive data with the processor 39 in units of a rank including thirty-two channels.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A memory device comprising:
a base die; and
a plurality of core dies stacked over the base die and connected to the base die using a plurality of through vias and a plurality of bump pads,
wherein the base die is configured to output a test code as a read code through an output pad in synchronization with a first edge of a test clock signal in a normal mode and configured to output the test code as the read code through the output pad in synchronization with the first edge and a second edge of the test clock signal in an acceleration mode.

2. The memory device of claim 1, wherein the base die comprises a test code storage circuit configured to store the test code including information on test results determining whether through vias included in the base die and each of the plurality of core dies are open circuits or short circuits.

3. The memory device of claim 1, wherein the base die comprises a selection clock generation circuit configured to generate a selection clock signal based on the test clock signal and an acceleration mode signal.

4. The memory device of claim 3, wherein the selection clock generation circuit configured to receive the acceleration mode signal, deactivated in the normal mode, and generate the test clock signal as the selection clock signal.

5. The memory device of claim 3, wherein the selection clock generation circuit configured to receive the acceleration mode signal, activated in the acceleration mode, and generate the selection clock signal including pulses generated at the first and second edges of the test clock signal.

6. The memory device of claim 3, wherein the base die further comprises a code output circuit configured to output the test code as the read code through the output pad in synchronization with the selection clock signal.

7. The memory device of claim 3, wherein the selection clock generation circuit comprises:
a delay unit configured to delay the test clock signal by a preset delay period to generate a delayed test clock signal;
an acceleration clock generator configured to generate an acceleration clock signal based on the test clock signal and the delayed test clock signal; and
a selector configured to generate the selection clock signal based on the acceleration mode signal, the acceleration clock signal, and the test clock signal.

8. The memory device of claim 7, wherein the acceleration clock generator is configured to generate the acceleration clock signal including pulses that occur at the first and second edges of the test clock signal.

9. The memory device of claim 7, wherein the selector is configured to receive the acceleration mode signal, deactivated in the normal mode, and select the test clock signal as the selection clock signal.

10. The memory device of claim 9, wherein the selector is configured to receive the acceleration mode signal, activated in the acceleration mode, and select the acceleration clock signal as the selection clock signal.

11. The memory device of claim 3, wherein the base die further comprises a test mode control circuit configured to generate the test clock signal and the acceleration mode signal in a test read mode, the test read mode including the normal mode and the acceleration mode.

12. A memory system comprising:
an interposer stacked over a substrate; and
a memory device and a processor stacked over the interposer and connected to each other through wires formed in the interposer,
wherein the memory device comprises a base die and a plurality of core dies stacked over the interposer,
wherein the base die and the plurality of core dies are connected to each other using a plurality of through vias and a plurality of bump pads, and
wherein the base die is configured to output a test code as a read code through an output pad in synchronization with a first edge of a test clock signal in a normal mode and configured to output the test code as the read code through the output pad in synchronization with the first edge and a second edge of the test clock signal in an acceleration mode.

13. The memory system of claim 12, wherein the base die comprises a test code storage circuit configured to store the test code including information on test results determining whether through vias included in the base die and each of the plurality of core dies are open circuits or short circuits.

14. The memory system of claim 12, wherein the base die comprises a selection clock generation circuit configured to generate a selection clock signal based on the test clock signal and an acceleration mode signal.

15. The memory system of claim 14, wherein the selection clock generation circuit is configured to:
receive the acceleration mode signal, deactivated in the normal mode, and generate the test clock signal as the selection clock signal, and
receive the acceleration mode signal, activated in the acceleration mode, and generate the selection clock signal including pulses generated at the first and second edges of the test clock signal.

16. The memory system of claim 14, wherein the base die further comprises a code output circuit configured to output the test code as the read code through the output pad in synchronization with the selection clock signal.

17. The memory system of claim 14, wherein the selection clock generation circuit comprises:
a delay unit configured to delay the test clock signal by a preset delay period to generate a delayed test clock signal;
an acceleration clock generator configured to generate an acceleration clock signal based on the test clock signal and the delayed test clock signal; and
a selector configured to generate the selection clock signal based on the acceleration mode signal, the acceleration clock signal, and the test clock signal.

18. The memory system of claim 17, wherein the acceleration clock generator is configured to generate the acceleration clock signal including pulses that occur at the first and second edges of the test clock signal.

19. The memory system of claim 17, wherein the selector is configured to:
receive the acceleration mode signal, deactivated in the normal mode, and select the test clock signal as the selection clock signal, and
receive the acceleration mode signal, activated in the acceleration mode, and select the acceleration clock signal as the selection clock signal.

20. The memory system of claim 14, wherein the base die further comprises a test mode control circuit configured to generate the test clock signal and the acceleration mode signal in a test read mode, the test read mode including the normal mode and the acceleration mode.
